(19) United States
(12) Patent Application Publication
(10) Pub. No.: US 2026/0035829 A1
(43) Pub. Date: Feb. 5, 2026

(54) QUARTZ GLASS CRUCIBLE FOR SILICON SINGLE-CRYSTAL PULLING AND MANUFACTURING METHOD UTILIZING SAME

(71) Applicant: SUMCO Corporation, Tokyo (JP)

(72) Inventors: Susumu TAMAOKI, Akita (JP); Masami OHARA, Akita (JP); Eriko KITAHARA, Akita (JP)

(73) Assignee: SUMCO Corporation, Tokyo (JP)

(21) Appl. No.: 19/124,059

(22) PCT Filed: Sep. 19, 2023
(86) PCT No.: PCT/JP2023/033899

§ 371 Date: Apr. 24, 2025

(30) Foreign Application Priority Data
Oct. 25, 2022 (JP) 2022-170468

(51) Int. Cl. C30B 15/10; C30B 29/06

(52) U.S. Cl. CPC C30B 15/10; C30B 29/06

(57) ABSTRACT

A quartz glass crucible includes a crucible main body consisting of silica glass, and a semi-molten layer consisting of a fusion-bonded layer of unmolten or semi-molten quartz powder formed on the outer side of an outer surface of the crucible main body. A number of recesses having a diameter of 0.2 mm or more and 5.0 mm or less and a depth of 50 μm or more are formed on a surface of the semi-molten layer. Some of the recesses are through-holes penetrating the semi-molten layer to reach an outer surface of the crucible main body, and the density of the through-holes is 1 through-hole/cm² or more and 50 through-holes/cm² or less.

### TECHNICAL FIELD

The present invention relates to a quartz glass crucible for pulling up a silicon single crystal, and a method for producing the same. In addition, the present invention relates to a method for producing a silicon single crystal using such a quartz glass crucible.

### BACKGROUND ART

A quartz glass crucible (silica glass crucible) is used for producing a silicon single crystal by a Czochralski method (CZ method). In the CZ method, a polycrystalline silicon raw material is molten in a quartz glass crucible to generate a silicon melt, a seed crystal is immersed in the silicon melt, and the seed crystal is gradually pulled up while rotating the quartz glass crucible and the seed crystal, thereby growing large single crystals at the lower end of the seed crystal. According to the CZ method, the yield of the large-diameter silicon single crystals can be increased.

The quartz glass crucible is a silica glass container that holds a silicon melt during a silicon single crystal pulling-up step. The inner side portion (inner layer) of the quartz glass crucible is formed of a transparent glass layer, which comes into contact with the silicon melt and thus contains substantially no bubbles, and the outer side portion (outer layer) is formed of a bubble-containing layer including a number of bubbles in order to disperse the radiant heat from the outside to uniformly heat the inside of the crucible.

A rotating mold method is known as the method for producing a quartz glass crucible. This production method is a method for producing a crucible, the method including heating quartz powder deposited on an inner surface of a rotating mold from a center side of the mold to vitrify the quartz powder, thereby producing a crucible, in which a transparent glass layer can be formed in the inside of the crucible by sucking air in a quartz powder-deposited layer from the mold side during melting and removing bubbles in a glass layer.

With regard to a quartz glass crucible, for example, Patent Literature 1 describes a quartz glass crucible in which an outer surface roughness of a lower portion to an R portion of a straight body portion of an opaque outer layer is larger than an outer surface roughness of an upper portion to a middle portion of the straight body portion, and larger than an outer surface roughness of a bottom portion; and a method for producing the same. The outer surface roughness of the upper portion to the middle portion of the straight body portion is 5 μm or more and 50 μm or less, whereas the outer surface roughness of the lower portion to the R portion of the straight body portion is 30 μm or more and 100 μm or less.

In addition, Patent Literature 2 describes a quartz glass crucible having an outer surface layer formed of a bubble-containing quartz glass layer, an inner surface layer formed of a quartz glass layer in which bubbles are not observed with the naked eye, and a semi-molten quartz layer formed of an unmolten or semi-molten quartz layer formed on a surface of the outer surface layer, in which a centerline average roughness (Ra) of the semi-molten quartz layer is 50 μm to 200 μm.

Recently, as the size of a crucible increases, the temperature of the crucible during pull-up tends to increase. In a case where the temperature of the crucible increases, the viscosity of the glass decreases, and there is a concern that the crucible may be deformed during use. As a measure against this, a method in which a crystallization accelerator is applied onto or incorporated into a surface of a crucible, and glass is crystallized at a high temperature to increase the strength of the crucible is known. In addition, a quartz glass crucible having a three-layer structure, in which an outer layer of the crucible is an Al-added quartz layers, an interlayer is a natural quartz layer or a high-purity synthetic quartz layer, and an inner layer is a transparent high-purity synthetic quartz layer, is also known (see Patent Literature 3).

### BACKGROUND ART LITERATURE

### Patent Literature

Patent Literature 1: Japanese Patent Laid-open Publication No. 2020-200199
Patent Literature 2: Japanese Patent Laid-open Publication No. 2009-84114
Patent Literature 3: Japanese Patent Laid-open Publication No. 2000-247778

### SUMMARY OF INVENTION

### Problems to be Solved by the Invention

As described above, the quartz glass crucible is strongly required to have durability so that the quartz glass crucible can withstand a long-duration crystal pulling-up step, and a method in which an outer surface of the crucible is crystallized or a method in which Al is added is effective, but further improvement of the durability of the crucible is required.

Therefore, an object of the present invention is to provide a quartz glass crucible, in which a thickness of a crystal layer at a time of crystallization of an outer surface of the crucible is large, and the crucible can withstand a long-duration crystal pulling-up step; and a method for producing the same. Another object of the present invention is to provide a method for producing a silicon single crystal, which makes it possible to grow a long and high-quality silicon single crystal by performing a long-duration crystal pulling-up step.

### Means for Solving the Problems

In order to solve the problems, a quartz glass crucible for pulling up a silicon single crystal according to an aspect of the present invention includes a crucible main body consisting of silica glass, and a semi-molten layer consisting of a fusion-bonded layer of unmolten or semi-molten quartz powder formed on an outer side of an outer surface of the crucible main body, in which a number of recesses having a diameter of 0.2 mm or more and 5.0 mm or less are formed on a surface of the semi-molten layer, some of the recesses are through-holes penetrating the semi-molten layer to reach the outer surface of the crucible main body, and the density of the through-holes is 1 through-hole/cm² or more and 50 through-holes/cm² or less.

According to the present invention, the crystallization rate of the outer surface of the crucible can be increased to form a thick crystal layer. Therefore, it is possible to improve the durability of the crucible at a high temperature during the crystal pulling-up, and it is also possible to provide a crucible that can withstand a long-duration crystal pulling-up step. Although there are also recesses on an outer surface of a quartz glass crucible in the related art, the number of deep recesses penetrating the semi-molten layer to reach the glass layer is small. Thus, the crystallization rate of the outer surface is slow, and the thickness of the crystal layer at a time of crystallization of the outer surface is small. Therefore, the durability of the quartz glass crucible was low and the quartz glass crucible could not withstand a long-duration crystal pulling-up step. However, according to the present invention, the number of recesses reaching the glass layer is large, and thus, crystallization into the wall is likely to proceed at a time of crystallization of an outer surface of the crucible and the thickness of the crystal layer can be increased.

In the present invention, the thickness of the semi-molten layer is preferably 50 μm or more. In a case where the thickness of the semi-molten layer is 50 μm or more, crystallization of the outer surface of the crucible is promoted, making it possible to form a thick crystal layer.

It is preferable that the quartz glass crucible according to the present invention has a cylindrical sidewall portion, a bottom portion, and a corner portion provided between the sidewall portion and the bottom portion, a wall thickness of the corner portion is greater than the wall thickness of the sidewall portion and the bottom portion, and a region where the through-holes are formed is provided at least over an entire periphery of the corner portion. As described above, since the deep recesses penetrating the semi-molten layer are distributed at least over the entire periphery of the corner portion, crystallization of the corner portion of the crucible can be promoted and deformation such as sinking of the crucible can be effectively suppressed.

In addition, the method for producing a quartz glass crucible according to the present invention includes a step of heating quartz powder deposited on an inner surface of a rotating mold from a center side of the mold to vitrify the quartz powder, a step of taking out the quartz glass crucible from the mold after cooling, and a step of subjecting a semi-molten layer consisting of a fusion-bonded layer of unmolten or semi-molten quartz powder formed on an outer surface of the quartz glass crucible to a honing treatment, in which a thermal conductivity of the quartz powder that form a natural silica glass layer of the quartz glass crucible at 750° C. is 0.5 W/(m·K) or more and 10 W/(m·K) or less.

According to the present invention, it is possible to produce a quartz glass crucible, in which a semi-molten layer consisting of a fusion-bonded layer of unmolten or semi-molten quartz powder is formed on an outer surface of a crucible main body consisting of silica glass, a number of recesses having a diameter of 0.2 mm or more and 5.0 mm or less are formed on a surface of the semi-molten layer, some of the recesses are through-holes reaching the outer surface of the crucible main body, and a density of the through-holes is 1 through-hole/cm² or more and 50 through-holes/cm² or less.

In the present invention, the average particle diameter of the quartz powder is preferably 150 μm or more and less than 400 μm. By using such the quartz powder, the production yield of the quartz glass crucible having the properties can be increased.

In the present invention, it is preferable that the mold has a cavity that matches an outer shape of the quartz glass crucible, and an opening size of the cavity corresponding to the sidewall portion of the quartz glass crucible is 1.01 times or more and 1.15 times or less a target outer diameter of the sidewall portion. By using such a mold, the production yield of the quartz glass crucible having the properties can be increased.

Furthermore, in the method for producing a silicon single crystal according to the present invention, a silicon melt is generated by melting a polycrystalline silicon raw material in a quartz glass crucible having the properties and the silicon single crystal is pulled up from the silicon melt. According to the present invention, it is possible to grow a long and high-quality silicon crystal by performing a long-duration crystal pulling-up step.

### Effects of the Invention

According to the present invention, it is possible to provide a quartz glass crucible in which a thickness of a crystal layer at a time of crystallization of an outer surface of the crucible is large and the quartz glass crucible can withstand a long-duration crystal pulling-up step, and a method for producing the same. In addition, according to the present invention, it is possible to provide a method for producing a silicon single crystal, by which it is possible to grow a long and high-quality silicon single crystal by carrying out a long-duration crystal pulling-up step.

### BRIEF DESCRIPTION OF THE DRAWINGS

FIG. 1 is a schematic perspective view showing a configuration of a quartz glass crucible according to an embodiment of the present invention.

FIG. 2 is a schematic side view of the quartz glass crucible according to the embodiment, in which the left half is a cross-sectional view and the right half is an external view.

FIG. 3 is a schematic cross-sectional view of a semi-molten layer in which recesses are formed.

FIG. 4 is a schematic cross-sectional view showing a state of the semi-molten layer according to the present invention before and after heating, as compared with the related art. In [FIG. 4] (a) shows a state of a crucible according to the related art before heating, (b) shows a state of the crucible according to the related art after heating, (c) shows a state of a crucible according to the present invention before heating, and (d) shows a state of the crucible according to the present invention after heating.

FIG. 5 is a schematic view showing a method for producing a quartz glass crucible according to an embodiment of the present invention.

FIG. 6 is a view for explaining a single crystal pulling-up step using the quartz glass crucible according to the present embodiment, which is a schematic cross-sectional view showing a configuration of a single crystal pulling-up apparatus.

FIG. 7 is a graph showing the results of one-way analysis of deformation amounts of crucible samples 1 to 10 after a heating test.

### MODE FOR CARRYING OUT THE INVENTION

Hereinafter, preferred embodiments of the present invention are described in detail with reference to the accompanying drawings.

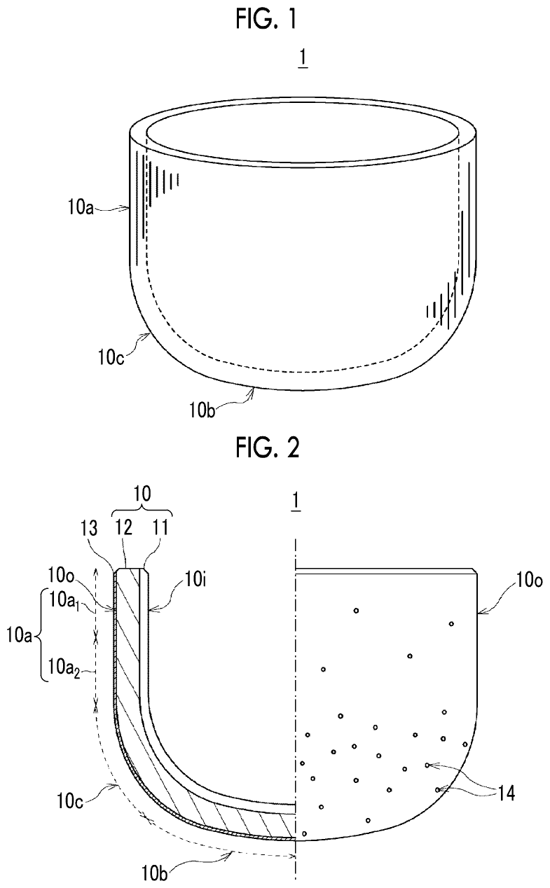

FIG. 1 is a schematic perspective view showing the configuration of a quartz glass crucible according to an embodiment of the present invention.

As shown in FIG. 1, a quartz glass crucible 1 is a silica glass container for holding a silicon melt, the container having a cylindrical sidewall portion 10a, a bottom portion 10b provided below the sidewall portion 10a, and a corner portion 10c provided between the sidewall portion 10a and the bottom portion 10b. The bottom portion 10b is preferably a so-called round bottom that is gently curved, but may also be a so-called flat bottom. The corner portion 10c is a portion having a larger curvature than the bottom portion 10b. The boundary between the side portion 10a and the corner portion 10c and the boundary between the corner portion 10c and the bottom portion 10b can be determined from points of change in curvature. The boundary between the sidewall portion 10a and the corner portion 10c in FIG. 2 is slightly shifted from the point of change in curvature, which is different from the explanation given here. Therefore, FIG. 2 may be slightly modified.

The aperture (diameter) of the quartz glass crucible 1 also varies depending on the diameter of a silicon single crystal ingot that is pulled up from the silicon melt, but is 18 inches (approximately 450 mm) or more, preferably 22 inches (approximately 560 mm), and particularly preferably 32 inches (approximately 800 mm) or more. This is because such a large crucible is used for pulling up a large silicon single crystal ingot having a diameter of 300 mm or more, and is required not to affect the quality of the single crystal even with the long duration use.

The wall thickness of the crucible varies slightly depending on its part, but it is preferable that the wall thickness of the sidewall portion 10a of the crucible with a diameter of 18 inches or more is 6 mm or more, and the wall thickness of the sidewall portion 10a of the crucible with a diameter of 22 inches or more is 7 mm or more, and the wall thickness of the sidewall portion 10a of the crucible with a diameter of 32 inches or more is 10 mm or more. As a result, a large amount of the silicon melt can be stably held at a high temperature. It is preferable that the wall thickness of the corner portion 10c of the crucible is the largest and the wall thickness of the sidewall portion 10a and the bottom portion 10b of the crucible is smaller than that of the corner portion 10c of the crucible.

FIG. 2 is a schematic side view of the quartz glass crucible 1 according to the present embodiment, in which the left half is a cross-sectional view and the right half is an external view.

As shown in FIG. 2, the quartz glass crucible 1 includes a crucible main body 10 made of silica glass and a semi-molten layer 13 formed on an outer surface 100 of the crucible main body 10. The crucible main body 10 is a two-layer structure, in which a transparent layer 11 including no bubbles (non-bubble layer) and a bubble layer 12 including a number of minute bubbles (opaque layer) are included, and the semi-molten layer 13 is provided outside the bubble layer 12. A crystallization accelerator may be applied or added to the outer surface of the semi-molten layer 13.

The transparent layer 11 is a glass layer constituting an inner surface 10i of the crucible main body 10, in which the glass layer comes into contact with the silicon melt, and is provided to prevent a yield of the silicon single crystals from decreasing due to bubbles in the silica glass. Since the inner surface 10i of the crucible reacts with the silicon melt to melt away, the bubbles in the vicinity of the inner surface of the crucible cannot be trapped in the silica glass and the bubbles burst due to thermal expansion, and thus, the crucible fragments (silica fragments) may be peeled. In a case where the crucible fragments released into the silicon melt are transported to a growth interface of the silicon single crystal by melt convection and incorporated into the silicon single crystal, they cause dislocation in the single crystal. In addition, in a case where the bubbles released into the silicon melt float up and reach a solid-liquid interface and are incorporated into the single crystal, they cause pinhole formation in the silicon single crystal.

The expression, including no bubbles in the transparent layer 11, means having a bubble content and a bubble size to the extent that the single crystallization rate does not decrease due to the bubbles. Such a bubble content is, for example, 0.1% by volume or less, and such as bubble diameter is, for example, 100 μm or less.

The thickness of the transparent layer 11 is preferably 0.5 to 10 mm, and is set to an appropriate thickness for each part of the crucible such that the bubble layer 12 is not exposed by completely vanishing the transparent layer 11 due to melting away during a crystal pulling-up step. The transparent layer 11 is preferably provided over the entire crucible from the sidewall portion 10a to the bottom portion 10b of the crucible, but it is also possible to omit the transparent layer 11 in the upper end portion of the crucible, which does not come into contact with the silicon melt.

The bubble layer 12 is a principal glass layer of the crucible main body 10 located on the outer side than the transparent layer 11, and is provided to improve the heat retention property of the silicon melt in the crucible, and to heat the silicon melt in the crucible as uniformly as possible by dispersing radiant heat from a heater in a single crystal pulling-up apparatus. Therefore, the bubble layer 12 is provided over the entire crucible from the sidewall portion 10a to the bottom portion 10b.

The bubble content of the bubble layer 12 is greater than that of the transparent layer 11 and is preferably more than 0.1% by volume and 5% by volume or less. This is because in a case where the bubble content of the bubble layer 12 is 0.1% by volume or less, the bubble layer 12 cannot exhibit a required heat retention function. In addition, this is because in a case where the bubble content of the bubble layer 12 is more than 5% by volume, the crucible may be deformed due to the thermal expansion of the bubbles and decrease the yield of the single crystals, and further the heat transfer property is insufficient. From the viewpoint of a balance between the heat retention property and the heat transfer property, the bubble content of the bubble layer 12 is particularly preferably 1% to 4% by volume. It should be noted that the above-described bubble content is a value obtained by measuring an unused crucible in a room temperature environment.

The semi-molten layer 13 is a layer formed on the outer surface of the crucible in a case where some of the quartz powder as a raw material for the crucible are cooled in an incompletely molten state (semi-molten state). The semi-molten layer 13 has a surface rich in undulations and has a thickness of 50 to 2,000 μm. The thickness of the semi-molten layer 13 is thinner as a temperature gradient in the vicinity of the outer surface is steeper during the production of the crucible, and is thicker as the temperature gradient is gentler. Since the temperature gradient is different for each part of the crucible, the thickness of the semi-molten layer 13 slightly varies for each part of the crucible. The thickness of the semi-molten layer 13 can be acquired by measuring the cross-section of the sample cut out from the crucible.

Whether or not the semi-molten layer 13 is formed on the outer surface of the crucible can be determined by whether or not a halo pattern in which a diffraction image unique to an amorphous material is blurred exists together with a peak showing crystallinity in a case where the outer surface of the crucible is measured by an X-ray diffraction method. In a case where the target to be measured is a crystal layer, the peak showing crystallinity is detected, but the halo pattern in which a diffraction image is blurred is not detected. In a case where the semi-molten layer 13 is removed, a surface of the glass is exposed, and thus, no peak is detected.

A number of recesses 14 are formed on a surface of the semi-molten layer 13 (outer surface of the crucible). The recesses 14 play a role of promoting crystallization of the outer surface of the crucible. In particular, by forming a large number of deep recesses 14 penetrating the semi-molten layer 13 to reach the glass layer 15, a thick crystal layer can be formed on the outer surface of the crucible.

The recess 14 can be easily confirmed and distinguished by visual observation, and has a concave shape that is clearly different from the surroundings. The diameter of the recess 14 is 0.2 to 5.0 mm, more preferably 0.3 to 2.0 mm, and still more preferably 0.5 to 1.0 mm. In a case where the diameter is less than 0.2 mm, the crystallization does not proceed to a thickness of the crystal layer at which deformation of the crucible can be suppressed. On the other hand, in a case where the thickness is more than 5.0 mm, the outer surface of the crucible is excessively crystallized, and thus, cracks in the crystal layer are likely to occur and deformation of the crucible occurs. The opening shape of the recess is often elliptical and the diameter in this case is defined as a maximum diameter of the opening.

The depth of the recess 14 is 50 to 2,100 μm, more preferably 50 to 1,000 μm, and still more preferably 50 to 300 μm. In a case where the depth of the recess 14 is less than 50 μm, the crystallization does not proceed to a thickness of the crystal layer at which deformation of the crucible can be suppressed. On the other hand, in a case where the depth is more than 2,100 μm, the outer surface of the crucible is excessively crystallized, and thus, cracks in the crystal layer are likely to occur and deformation of the crucible occurs.

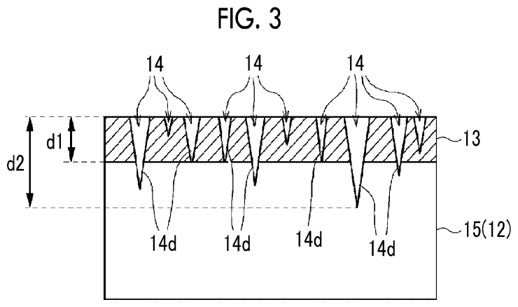

FIG. 3 is a schematic cross-sectional view of the semi-molten layer in which recesses are formed.

As shown in FIG. 3, some of a number of recesses 14 are through-holes 14d penetrating the semi-molten layer 13, the bottom portions of which reach the glass layer 15 (that is, the bubble layer 12) constituting the crucible main body 10, and some of which reach the inside of the glass layer 15. Since the glass layer 15 is exposed through the recesses 14, heat is easily transferred to the glass layer 15 and the glass layer 15 is likely to be crystallized. In comparison of the crystallization rate of the glass layer 15 with that of the semi-molten layer 13, the crystallization rate of the glass layer 15 is greater. Since some of the recesses 14 reach the glass layer 15, crystallization in the wall is likely to proceed at a time of crystallization of an outer surface of the crucible, and the thickness of the crystal layer can be increased.

The density of the deep recesses 14 (through-holes 14d) penetrating the semi-molten layer 13 is preferably 1 to 50 recesses/cm², more preferably 2 to 30 recesses/cm², and still more preferably 5 to 20 recesses/cm². In a case where the density of the deep recesses 14 penetrating the semi-molten layer 13 is less than 1 recess/cm², the crystallization does not proceed to a thickness of the crystal layer at which deformation of the crucible can be suppressed. On the other hand, in a case where the number of deep recesses is more than 50 recesses/cm², the outer surface of the crucible is excessively crystallized, cracks in the crystal layer are likely to occur, and deformation of the crucible occurs.

The thickness d₁ of the semi-molten layer 13 is less than the maximum depth d₂ of the recesses 14. The thickness of the semi-molten layer 13 is preferably in a range of 50 to 2,000 μm, more preferably in a range of 100 to 1,000 μm, and still more preferably in a range of 100 to 500 μm. In a case where the thickness of the semi-molten layer 13 is less than 50 μm, the crystallization does not proceed to a thickness of the crystal layer at which deformation of the crucible can be suppressed. On the other hand, in a case where the thickness is more than 2,000 μm, the probability that the crucible is deformed due to the occurrence of the outer surface peeling caused by a difference in thermal expansion coefficient between the semi-molten layer 13 and the glass layer 15 during the pulling-up of the silicon single crystal increases.

It is preferable that the through-hole 14d is provided at least in the corner portion 10c of the crucible, and distributed over the entire periphery of the corner portion 10c. It is more preferable that the through-hole 14d is provided over the entire periphery of the crucible from the lower portion 10a2 of the sidewall portion 10a to the corner portion 10c. As described above, since a number of through-holes 14d are provided in the corner portion 10c of the crucible, crystallization of the outer surface of the crucible can be promoted to improve the strength of the crucible, and particularly, buckling and sinking at the corner portion of the crucible can be effectively suppressed.

The corner portion 10c is a portion that is likely to be heated to a high temperature, and buckling and sinking are likely to occur. Recently, multi-pull-ups are often performed and the crucible is exposed to a high temperature for a long duration. Therefore, buckling and sinking of the corner portion are likely to occur. In a case where buckling or sinking of the crucible occurs, a probability of peeling of fine pieces of the crucible (silica pieces) from the inner surface of the corner portion 10c increases. In a case where the crucible pieces are transported to a growth interface of the silicon single crystal by melt convection and incorporated into the silicon single crystal, they cause dislocation in the single crystal. However, in a case where the strength of the crucible is improved by promoting the crystallization of the corner portion of the crucible as described above, the peeling of the fine silica pieces can be suppressed and the dislocation of the silicon single crystal can be prevented.

The region where the recesses 14 are formed may or may not be provided in the upper portion 10a1 of the sidewall portion 10a or the bottom portion 10b. In a case where the recesses 14 are formed in the sidewall portion 10a or the bottom portion 10b, the recesses 14 may be deep recesses (through-holes 14d) that reach the glass layer 15, or shallow recesses (non-through-holes) that do not reach the glass layer 15.

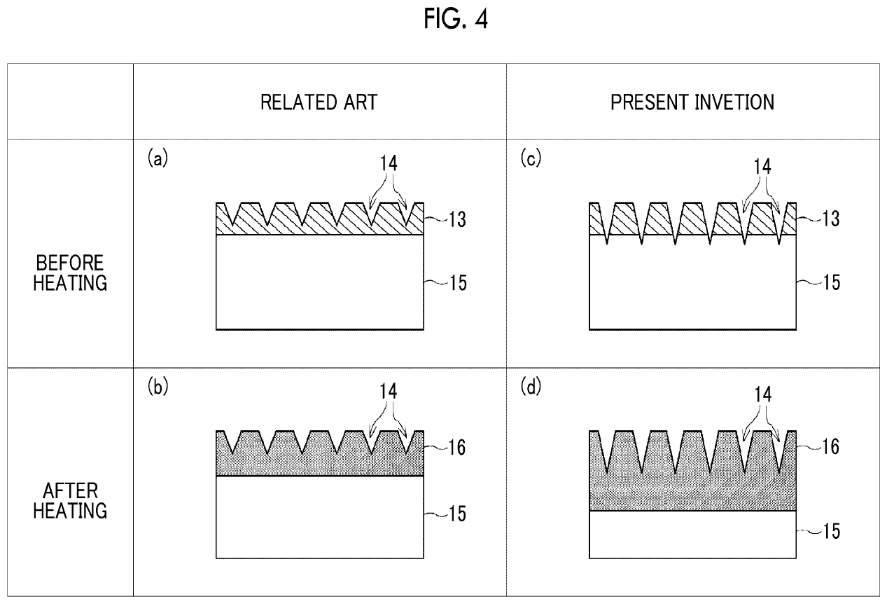

FIG. 4 is a schematic cross-sectional view showing a state of the semi-molten layer 13 according to the present invention before and after heating, as compared with the related art.

As shown in FIG. 4(a), the recesses 14 were present in a semi-molten layer 13 of a quartz glass crucible in the related art, but the depths of the recesses 14 were shallow and did not reach a glass layer 15. Therefore, as shown in FIG. 4(b), the crystal layer 16 cannot be formed to be thick even at a time of crystallization of the outer surface of the crucible by heating in the crystal pulling-up step.

On the other hand, as shown in FIG. 4(c), most of the recesses 14 formed in the semi-molten layer 13 of the quartz glass crucible according to the present invention reach the glass layer 15, and some of the recesses 14 further extend deeper than the surface of the glass layer 15. Thus, heat is easily transferred to the deep portion of the crucible. Therefore, as shown in FIG. 4(d), at a time of crystallization of an outer surface of the crucible by heating during the crystal pulling-up step, the crystal layer 16 can be formed to be thick, and thus, the strength of the crucible can be improved.

In order to prevent the contamination of the silicon melt, the silica glass constituting the transparent layer 11 is desirably at a high purity. Therefore, it is preferable that the quartz glass crucible 1 has a two-layer structure of a synthetic silica glass layer (synthetic layer) formed of synthetic quartz powder (synthetic silica powder) and a natural silica glass layer (natural layer) formed of natural quartz powder. The synthetic quartz powder can be produced by vapor-phase oxidation (dry synthesis method) of silicon tetrachloride (SiCl₄) or hydrolysis of silicon alkoxide (sol-gel method), and are preferably used as a raw material for forming an inner surface of a crucible in contact with a silicon melt. In addition, the natural quartz powder are produced by pulverizing a natural mineral having a-quartz as a main component into granules. The natural quartz powder are naturally produced crystalline quartz powder and are relatively inexpensive. Thus, the natural quartz powder are preferably used as a main raw material for the crucible.

The two-layer structure with the synthetic silica glass layer and the natural silica glass layer can be produced by depositing natural quartz powder along an inner surface of a mold for producing a crucible, depositing synthetic quartz powder thereon, and melting these raw material quartz powder with Joule heat generated by arc discharge. In the arc melting step, bubbles are removed by strong evacuation from the outside of the quartz powder-deposited layer to form the transparent layer 11, and the stopping or weakening the evacuation to form the bubble layer 12. Therefore, the interface between the synthetic silica glass layer and the natural silica glass layer does not necessarily coincide with the interface between the transparent layer 11 and the bubble layer 12, but in the same manner as in the transparent layer 11, the synthetic silica glass layer preferably has a thickness to the extent that does not completely vanish due to melting away of the inner surface of the crucible during the single crystal pulling-up step.

The quartz glass crucible 1 according to the present embodiment can be produced by a so-called rotating mold method.

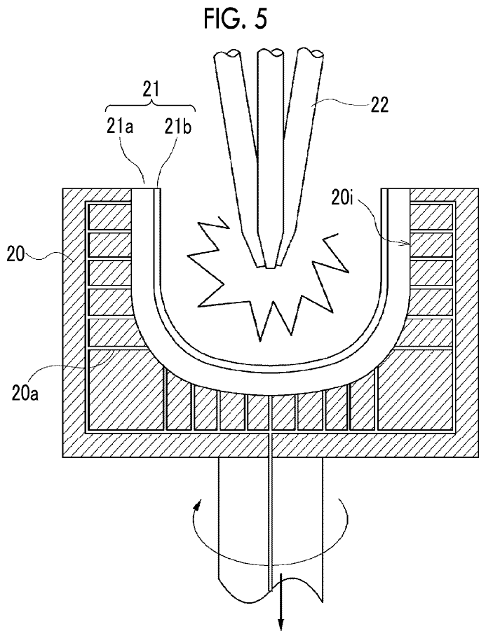

FIG. 5 is a schematic view showing a method for producing the quartz glass crucible 1 according to the embodiment of the present invention.

As shown in FIG. 5, in the production of the quartz glass crucible 1 by a rotating mold method, a mold 20 having a cavity corresponding to the outer shape of the crucible is used. The inner diameter of the mold 20 is preferably 1% to 15% wider than the target outer diameter of the sidewall portion of the crucible. That is, the opening size of the cavity is preferably 1.01 to 1.15 times the target diameter of the crucible. In this way, by making the opening size of the mold cavity wider than before, the diameter of the completed crucible can be adjusted to the target diameter.

Next, the natural quartz p powder 21a and the synthetic quartz powder 21b are sequentially filled along the inner surface 20i of the rotating mold 20 to form a quartz powder-deposited layer 21. The quartz powder stay in a fixed position while sticking to the inner surface 20i of the mold 20 by centrifugal force, and are maintained in a crucible shape. The thickness (height) of the quartz powder-deposited layer 21 is preferably greater than the target wall thickness in each part of the crucible, and is 1.06 to 1.1 times the target wall thickness.

The thermal conductivity of the natural quartz powder 21a is preferably 0.2 to 10 W/(m·K), more preferably 0.3 to 1.0 W/(m·K), and still more preferably 0.45 to 0.6 W/(m·K) at 750° C. In a case where raw material powder having a thermal conductivity in this range is used, a number of recesses having a desired depth are easily formed in the semi-molten layer 13 formed on the outer surface of the crucible. In a case where the thermal conductivity is less than 0.2 W/(m. K), recesses are not generated. On the other hand, in a case where the thermal conductivity is more than 10 W/(m·K), recesses are excessively generated, the outer surface of the crucible is excessively crystallized during the crystal pulling-up step, cracks are likely to occur in the crystal layer, and deformation of the crucible is caused. In addition, there is an issue that the melting of the raw material powder does not proceed, the outer diameter of the crucible increases, and the crucible does not enter the carbon susceptor used at a time of pulling up the silicon single crystal.

The average particle diameter of the natural quartz powder 21a is preferably 150 to 400 μm. In a case where the average particle diameter is less than 150 μm, the raw material powder melts excessively, causing a failure that the crucible cannot be taken out from the mold to occur. On the other hand, in a case where the average particle diameter is more than 400 μm, there is an issue that the melting of the raw material powder does not proceed, the outer diameter of the crucible increases, and the crucible cannot be installed in a carbon susceptor used at a time of pulling up the silicon single crystal.

Next, an arc electrode 22 is installed in the mold 20 and the quartz powder-deposited layer 21 is arc-molten from the inside of the mold 20. Specific conditions such as a heating time and a heating temperature are appropriately determined in consideration of conditions such as properties of the quartz powder and a size of the crucible.

In a case where quartz powder having a thermal conductivity of 0.2 to 10 W/(m·K) at 750° C. are used, even though the quartz powder-deposited layer 21 is heated, heat does not remain in the deposited layer 21 and easily escapes. Thus, there is a tendency that the outer diameter of the crucible is less likely to be increased. However, by increasing the opening size of the cavity of the mold 20 as described above to thicken the deposited layer 21, heat is likely to remain in the deposited layer 21, and the outer diameter of the crucible can thus be set to a desired diameter. As described above, the thickness of the quartz powder-deposited layer 21 is preferably 1.5 to 3.0 times the wall thickness of the crucible. In a case where the thickness of the quartz powder-deposited layer 21 increases, it is necessary to rotate the mold 20 at a higher speed.

During arc melting, the amount of bubbles in the molten silica glass is controlled by evacuating the quartz powder-deposited layer 21 from a number of vent holes 20a provided on the inner surface 20i of the mold 20. Specifically, at the start of the arc melting, the quartz powder-deposited layer 21 is evacuated to form the transparent layer 11, and after the formation of the transparent layer 11, the evacuation is stopped or the suction force is reduced to form the bubble layer 12.

Since the arc heat is gradually transferred from the inside to the outside of the quartz powder-deposited layer 21 to melt the quartz powder, the transparent layer 11 and the bubble layer 12 can be separately made by changing decompression conditions at a timing at which the quartz powder start to melt. That is, in a case where decompression melting for strengthening the decompression is performed at a timing at which the quartz powder melt, the arc atmospheric gas is not trapped in the glass, and thus, the molten quartz becomes silica glass including no bubbles. In addition, in a case where normal melting (atmospheric pressure melting) for weakening the decompression is performed at the timing at which the quartz powder melt, the arc atmospheric gas is trapped in the glass, and thus, the molten silica becomes silica glass including a number of bubbles.

Subsequently, the arc melting is terminated and the crucible is cooled. In particular, by terminating the arc heating before the quartz powder in the vicinity of the inner surface of the mold 20 are completely molten, it is possible to prevent the mold 20 from being closely attached to the glass layer, and thus, to easily take out the crucible from the mold 20. In addition, by terminating the arc heating before the quartz powder in the vicinity of the inner surface of the mold 20 is completely molten, the semi-molten layer 13 consisting of a fusion-bonded layer of the unmolten or semi-molten quartz powder can be formed on the outer surface of the crucible.

As described above, the quartz glass crucible 1 in which the transparent layer 11, the bubble layer 12, and the semi-molten layer 13 are sequentially provided from the inside to the outside of the crucible is completed.

Next, after the crucible is shaped into a predetermined shape by cutting the rim portion or the like, the outer surface of the crucible is subjected to a honing treatment to remove residues of quartz powder. In the honing treatment, it is preferable that the excess quartz powder are removed by spraying high-pressure pure water. This honing treatment can expose the recesses 14 on the surface of the semi-molten layer 13.

Thereafter, the crucible is cleaned with a cleaning liquid and further rinsed with pure water. The cleaning liquid is preferably prepared by diluting hydrofluoric acid of semiconductor grade or higher with pure water of TOC≤2 ppb to adjust to 10% to 40% by weight. In this way, a series of steps for producing the quartz glass crucible 1 are completed.

As described above, the quartz glass crucible 1 according to the present embodiment includes the crucible main body 10 consisting of silica glass and the semi-molten layer 13 formed on the outer surface 100 of the crucible main body 10, a number of the recesses 14 are formed on the surface of the semi-molten layer 13, and some of the recesses 14 reach the crucible main body 10. Thus, the crystallization of the outer surface of the crucible can be promoted to form the crystal layer to be thick, whereby the durability of the crucible can be improved.

In addition, in the method for producing the quartz glass crucible 1 according to the present embodiment, the quartz glass crucible is produced using quartz powder having a thermal conductivity of 0.2 W/(m·K) or more and 10 W/(m·K) or less at 750° C., which has a relatively high thermal conductivity, so that a quartz glass crucible having a number of deep recesses formed on the surface of the semi-molten layer can be produced.

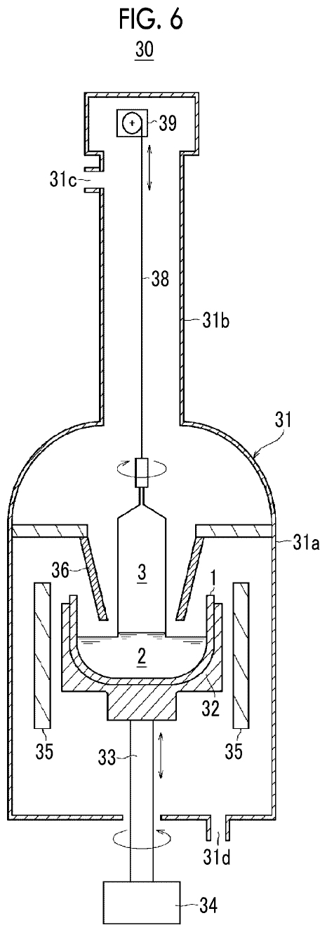

FIG. 6 is a view for explaining a single crystal pulling-up step using the quartz glass crucible 1 according to the present embodiment, in which the view is a schematic cross-sectional view showing a configuration of a single crystal pulling-up apparatus.

As shown in FIG. 6, a single crystal pulling-up apparatus 30 is used for the silicon single crystal pulling-up step by the CZ method. The single crystal pulling-up apparatus 30 includes a water-cooled chamber 31, a quartz glass crucible 1 that holds a silicon melt in the chamber 31, a carbon susceptor 32 that holds the quartz glass crucible 1, a rotating shaft 33 that supports the carbon susceptor 32 to be rotatable and vertically movable, a shaft driving mechanism 34 that drives the rotating shaft 33 to be rotated and vertically moved, a heater 35 that is arranged around the carbon susceptor 32, a substantially cylindrical heat shielding member 36 that is arranged above the quartz glass crucible 1, a wire 38 for pulling up a single crystal that is arranged above the quartz glass crucible 1 and is coaxial with the rotating shaft 33, and a wire winding mechanism 39 that is arranged above the chamber 31.

The chamber 31 is composed of a main chamber 31a and a slender cylindrical pull chamber 31b connected to an upper opening of the main chamber 31a, and the quartz glass crucible 1, the carbon susceptor 32, and the heater 35 are installed in the main chamber 31a. A gas entry 31c for introducing an inert gas (purge gas) such as an argon gas and a dopant gas into the main chamber 31a is provided in the upper portion of the pull chamber 31b, and a gas outlet 31d for discharging atmospheric gas inside the main chamber 31a is provided in the lower portion of the main chamber 31a.

The carbon susceptor 32 is used to maintain the shape of the quartz glass crucible 1 that is softened at high temperature, and holds the quartz glass crucible 1 to wrap around it. The quartz glass crucible 1 and the carbon susceptor 32 constitute a double-structured crucible supporting the silicon melt in the chamber 31.

The carbon susceptor 32 is fixed to the upper end portion of the rotating shaft 33, and the lower end portion of the rotating shaft 33 penetrates through the bottom portion of the chamber 31 and is connected to a shaft driving mechanism 34 provided outside of the chamber 31.

The heater 35 is used to melt the polycrystalline silicon raw material filled in the quartz glass crucible 1 to generate the silicon melt 2, as well as to maintain a molten state of the silicon melt 2. The heater 35 is a resistance heating type carbon heater, and is provided to surround the quartz glass crucible 1 in the carbon susceptor 32.

The heat shielding member 36 is a graphite-made member that covers an upper region of the silicon melt 2 excluding the pulling-up path of the silicon single crystal 3, and is provided to suppress a temperature fluctuation of the silicon melt 2 to form an appropriate hot zone in the vicinity of the solid-liquid interface, and to prevent the silicon single crystal 3 from being heated by the radiant heat from the heater 35 and the quartz glass crucible 1.

A circular opening having a diameter larger than the diameter of the silicon single crystal 3 is formed at the center of the lower end of the heat shielding member 36. Since the diameter of the opening 17a of the heat shielding member 36 is smaller than the diameter of the quartz glass crucible 1 and the lower end portion of the heat shielding member 36 is located inside the quartz glass crucible 1, even in a case where the upper end of the rim of the quartz glass crucible 1 rises above the lower end of the heat shielding member 36, the heat shielding member 36 does not interfere with the quartz glass crucible 1.

The heat shielding member 36 also functions as a gas rectifying member that rectifies the flow of gas in the vicinity of the surface of the silicon melt 2. The amount of the melt decreases with the growth of the silicon single crystal 3, and the melt surface in the quartz glass crucible 1 gradually decreases. However, by gradually raising the quartz glass crucible 1, the distance (gap value) from the melt surface of the silicon melt 2 to the lower end of the heat shielding member 36 can be maintained constant, and the flow rate of the gas flowing in the vicinity of the melt surface can thus be maintained constant. Therefore, it is possible to suppress the temperature fluctuation of the silicon melt 2 and control the amount of the dopant evaporated from the silicon melt 2, and it is possible to improve the stability of the distribution of crystal defects, the distribution of oxygen concentration, the distribution of resistivity, and the like in the pulling-up axis direction of the single crystal.

The wire winding mechanism 39 is arranged above the pull chamber 31b, the wire 38 extends downward from the wire winding mechanism 39 passing through the interior of the pull chamber 31b, and a tip portion of the wire 38 reaches the inner space of the main chamber 31a. This figure shows a state where the silicon single crystal 3 in the middle of growth is suspended on the wire 38. In a case where the silicon single crystal 3 is pulled up, the wire 38 is gradually pulled up while rotating the quartz glass crucible 1 and the silicon single crystal 3 individually to grow the silicon single crystal 3.

During the single crystal pulling-up step, the quartz glass crucible 1 is softened, but since the crystallization of the outer surface of the crucible proceeds, the strength of the crucible can be increased, and deformation such as sinking and inward collapse of the crucible can be suppressed. Therefore, it is possible to prevent the melt surface position of the silicon melt 2 from rapidly changing due to the change in the volume of the crucible or to prevent the crucible from coming into contact with the heat shielding member 36.

Although preferred embodiments of the present invention were described above, the present invention is not limited to the above-described embodiments, and various modifications are possible without departing from the scope of the present invention, and such modifications are, needless to say, covered by the scope of the present invention.

For example, in the embodiments, the semi-molten layer 13 is formed on the entire crucible from the bottom portion 10b to the upper end of the sidewall portion 10a of the crucible, but the semi-molten layer 13 may not be formed in the bottom portion 10b and the semi-molten layer 13 may not be formed in the vicinity of the upper end of the rim.

### Examples

Samples 1 to 10 of quartz glass crucibles produced by a rotating mold method were prepared, and the diameters (mm) of recesses formed over the entire periphery of the corner portion, the depths (μm) of the recesses, and the density (recesses/cm²) of deep recesses (through-holes) reaching the glass layer were evaluated. A surface roughness measuring instrument: SURFTEST SJ-301 manufactured by Mitutoyo Corporation was used for measuring the diameter and the depth of the recess. The measurement was performed at a measurement speed of 0.5 mm/sec. The recess diameter was measured by cutting out a sample from the quartz crucible. The arrival position of a tip of the recess was distinguished by irradiating the quartz crucible with a fluorescent lamp from the inner surface side thereof and visually observing from the outer surface side of the quartz crucible. That is, the diameter and the depth of the recess were measured by a machine, but the evaluation of whether or not the recess tip reached the glass layer was performed by visual confirmation. The measurement results are shown in Table 1. The crucible samples 1 to 6 are Comparative Examples and the samples 7 to 10 are Examples.

TABLE 1

| | Diameter | Depth | Density of | |
|---|---|---|---|---|
| | of | of | recesses reaching | Deformation |
| | recess | recess | glass layer | amount |
| Sample | (mm) | (μm) | (recesses/cm²) | (mm) |
| 1 | 0.13 | 149.3 | 23.8 | 7.9 |
| 2 | 7.90 | 102.9 | 19.4 | 9.3 |
| 3 | 2.41 | 21.8 | 19.0 | 8.5 |
| 4 | 4.03 | 47.1 | 31.5 | 10.3 |
| 5 | 0.27 | 56.0 | 0.8 | 8.7 |
| 6 | 1.58 | 179.5 | 52.1 | 9.7 |
| 7 | 0.24 | 51.2 | 1.3 | 2.3 |
| 8 | 1.85 | 94.9 | 12.6 | 2.9 |
| 9 | 3.16 | 79.4 | 29.2 | 2.5 |
| 10 | 4.51 | 127.6 | 46.1 | 3.4 |

Next, the thermal deformation resistance of the quartz glass crucibles of the samples 1 to 10 was evaluated. In the evaluation of the thermal deformation resistance, the sample was installed in a test furnace, and after holding the temperature at 1,500° C. for 50 hours, the crucible was taken out to evaluate the presence or absence of deformation. Specifically, the thermal deformation resistance was quantitatively evaluated by measuring the amount of a change (deformation amount) in the height of the crucible before and after the test. The evaluation results of the thermal deformation resistance are shown in Table 1.

As can be seen from Table 1, in the crucible samples 1 to 6, the height of the crucible changed and the crucible clearly sank. On the other hand, in the crucible samples 7 to 10, no significant sinking of the crucible was observed.

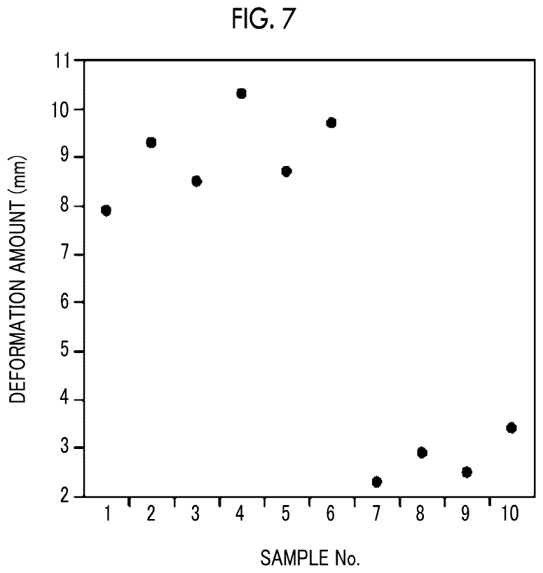

FIG. 7 is a graph showing the results of one-way analysis of the deformation amounts of the crucible samples 1 to 10 after the heating test in which the temperature was held at 1,500° C. for 50 hours.

As shown in FIG. 7, the deformation amounts of the crucible samples 1 to 6 were approximately 7.9 to 10.3 mm, while the deformation amounts of the crucible samples 7 to 10 were approximately 2.3 to 3.4 mm. Thus, it could be confirmed that the sinking amounts of crucible samples 7 to 10 were smaller.

### DESCRIPTION OF REFERENCE NUMERALS

1 Quartz glass crucible
2 Silicon melt
3 Silicon single crystal
10 Crucible main body
10a Sidewall portion
10a1 Upper portion of sidewall portion
10a2 Lower portion of sidewall portion
10b Bottom portion
10c Corner portion
10i Inner surface
100 Outer surface
11 Transparent layer
11 Quartz crucible
12 Bubble layer
13 Semi-molten layer
14 Recess
14d Through-hole (Deep recess)
15 Glass layer
16 Crystal layer
17a Opening
20 Mold
20a Vent hole
20i Inner surface of mold
21 Deposited layer
21a Natural quartz powder
21b Synthetic quartz powder
22 Arc electrode
30 Single crystal pulling-up apparatus
31 Chamber
31a Main chamber
31b Pull chamber
31c Gas entry
31d Gas outlet
32 Carbon susceptor
33 Rotating shaft
34 Shaft driving mechanism
35 Heater
36 Heat shielding member
38 Wire for pulling up single crystal
39 Wire winding mechanism

1. A quartz glass crucible for pulling up a silicon single crystal, the quartz glass crucible comprising:
a crucible main body consisting of silica glass; and
a semi-molten layer consisting of a fusion-bonded layer of unmolten or semi-molten quartz powder formed on an outer side of an outer surface of the crucible main body,
wherein a number of recesses having a diameter of 0.2 mm or more and 5.0 mm or less and a depth of 50 μm or more are formed on a surface of the semi-molten layer,
at least some of the recesses are through-holes penetrating the semi-molten layer to reach the outer surface of the crucible main body, and
a density of the through-holes is 1 through-hole/cm² or more and 50 through-holes/cm² or less.

2. The quartz glass crucible according to claim 1,
wherein a thickness of the semi-molten layer is 50 μm or more.

3. The quartz glass crucible according to claim 1,
wherein the quartz glass crucible has a cylindrical sidewall portion, a bottom portion, and a corner portion provided between the sidewall portion and the bottom portion,
a wall thickness of the corner portion is greater than the wall thickness of the sidewall portion and the bottom portion, and
a region where the through-holes are formed is provided at least over an entire periphery of the corner portion.

4. A method for producing a silicon single crystal by a Czochralski method, the method comprising:
melting a polycrystalline silicon raw material in the quartz glass crucible according to claim 1 to generate a silicon melt; and
pulling up a silicon single crystal from the silicon melt.

5. A method for producing a silicon single crystal by a Czochralski method, the method comprising:
melting a polycrystalline silicon raw material in the quartz glass crucible according to claim 2 to generate a silicon melt; and
pulling up a silicon single crystal from the silicon melt.

6. A method for producing a silicon single crystal by a Czochralski method, the method comprising:
melting a polycrystalline silicon raw material in the quartz glass crucible according to claim 3 to generate a silicon melt; and
pulling up a silicon single crystal from the silicon melt.
